(19) United States
(12) Patent Application Publication
(10) Pub. No.: US 2024/0274467 A1
(43) Pub. Date: Aug. 15, 2024

(54) Interconnect Structure of Semiconductor Device

(71) Applicant: Taiwan Semiconductor Manufacturing Co., Ltd., Hsinchu (TW)

(72) Inventors: Chia-Ching Tsai, Tainan (TW); Yi-Wei Chiu, Kaohsiung (TW); Li-Te Hsu, Shanhua Township (TW)

(21) Appl. No.: 18/646,870

(22) Filed: Apr. 26, 2024

Related U.S. Application Data
(63) Continuation of application No. 16/942,114, filed on Jul. 29, 2020, now Pat. No. 11,996,325.
Application No. 16/942,114 is a continuation of application No. 16/423,504, filed on May 28, 2019, now Pat. No. 10,763,162.
Application No. 16/423,504 is a continuation of application No. 15/587,140, filed on May 4, 2017, now Pat. No. 10,304,729.
(60) Provisional application No. 62/427,590, filed on Nov. 29, 2016.

(51) Int. Cl. H01L 21/768

(52) U.S. Cl. CPC H01L 21/76832; H01L 21/76804; H01L 21/76807; H01L 21/76813; H01L 21/76834; H01L 21/76879

(57) ABSTRACT

A device includes a substrate, a first dielectric layer over the substrate, a first conductive feature in the first dielectric layer, and an etch stop layer over the first dielectric layer. The etch stop layer includes metal-doped aluminum nitride. The device further includes a second dielectric layer over the etch stop layer, and a second conductive feature in the second dielectric layer. The second conductive feature extends into the etch stop layer and contacts the first conductive feature.

### PRIORITY CLAIM AND CROSS-REFERENCE

This application is a continuation of U.S. application Ser. No. 16/942,114, filed on Jul. 29, 2020, which is a continuation of U.S. application Ser. No. 16/423,504, filed on May 28, 2019, no U.S. Pat. No. 10,763,162, issued on Sep. 1, 2020, which is a continuation of U.S. application Ser. No. 15/587,140, filed on May 4, 2017, now U.S. Pat. No. 10,304,729, issued on May 28, 2019, which claims the benefit of U.S. Provisional Application No. 62/427,590, filed on Nov. 29, 2016, which applications are hereby incorporated herein by reference.

### BACKGROUND

Generally, active devices and passive devices are formed on and in a semiconductor substrate. Once formed, these active devices and passive devices may be connected to each other and to external devices using a series of conductive and insulative layers. These layers may help to interconnect the various active devices and passive devices as well as provide an electrical connection to external devices through, for example, a contact pad.

To form these interconnections within these layers, a series of photolithographic, etching, deposition, and planarization techniques may be employed. However, the use of such techniques has become more complicated as the size of active and passive devices have been reduced, causing a reduction in the size of the interconnects to be desired as well. As such, improvements in the formation and structure of the interconnects is desired in order to make the overall devices smaller, cheaper, and more efficient with fewer defects or problems.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7 illustrate cross-sectional views of various intermediate stages of fabrication of a semiconductor structure in accordance with some embodiments.

FIG. 8 is a flow diagram illustrating a method of forming a semiconductor structure in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will be described with respect to a specific context, namely, a method of forming interconnects in a semiconductor structure. Various embodiments discussed herein allow for preventing oxidation/corrosion of interconnects and allow for preventing formation of hydride and hydroxyl impurities within interconnects.

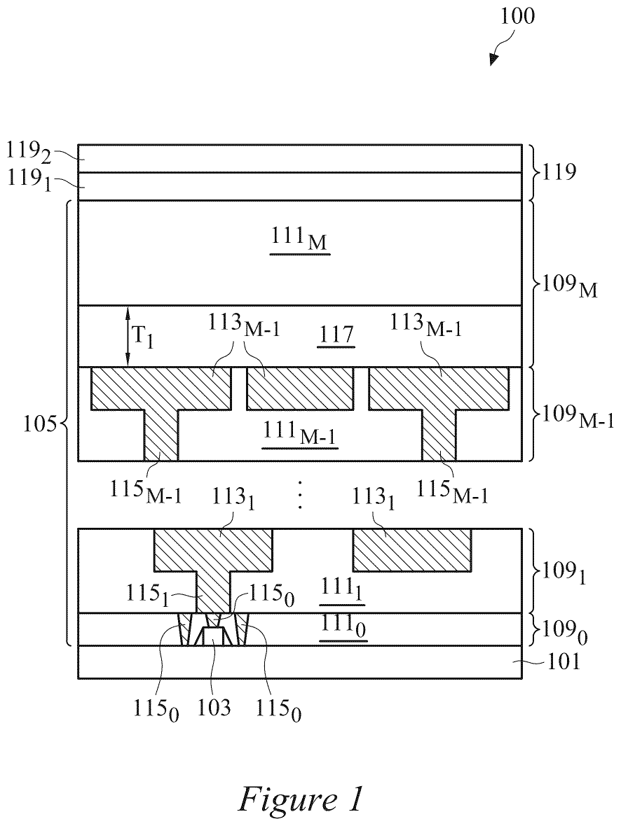

Referring to FIG. 1, a portion of the semiconductor structure 100 is illustrated. The semiconductor structure 100 may be an intermediate structure of an integrated circuit manufacturing process. In some embodiments, the semiconductor structure 100 may comprise a substrate 101. The substrate 101 may comprise, for example, bulk silicon, doped or undoped, or an active layer of a semiconductor-on-insulator (SOI) substrate. Generally, an SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Alternatively, the substrate 101 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In some embodiments, one or more active and/or passive devices 103 (illustrated in FIG. 1 as a single transistor) are formed on the substrate 101. The one or more active and/or passive devices 103 may include various N-type metal-oxide semiconductor (NMOS) and/or P-type metal-oxide semiconductor (PMOS) devices, such as transistors, capacitors, resistors, diodes, photo-diodes, fuses, and the like. One of ordinary skill in the art will appreciate that the above examples are provided for the purpose of illustration only and are not meant to limit the present disclosure in any manner. Other circuitry may be also used as appropriate for a given application.

In some embodiments, an interconnect structure 105 is formed over the one or more active and/or passive devices 103 and the substrate 101. The interconnect structure 105 electrically interconnects the one or more active and/or passive devices 103 to form functional electrical circuits within the semiconductor structure 100. The interconnect structure 105 may comprise one or more metallization layers 109₀ to 109_{M}, wherein M+1 is the number of the one or more metallization layers 109₀ to 109_{M}. In some embodiments, the value of M may vary according to design specifications of the semiconductor structure 100. In what follows, the one or more metallization layers 109₀ to 109_{M} may also be collectively referred to as the one or more metallization layers 109. The one or more metallization layers 109₀ to 109_{M}, comprise one or more dielectric layers 111₀ to 111_{M}, respectively.

In some embodiments, the dielectric layer 111₀ is an inter-layer dielectric (ILD) layer, and the dielectric layers 111₁ to 111_{M} are inter-metal dielectric (IMD) layers. The ILD layer and the IMD layers may include low-k dielectric materials having k values, for example, lower than about 4.0 or even 2.0 disposed between such conductive features. In some embodiments, the ILD layer and IMD layers may be made of, for example, phosphosilicate glass (PSG), borophosphosilicate glass (BPSG), fluorosilicate glass (FSG), SiOxCy, Spin-On-Glass, Spin-On-Polymers, silicon carbon material, compounds thereof, composites thereof, combinations thereof, or the like, formed by any suitable method, such as spin-on coating, chemical vapor deposition (CVD), plasma-enhanced CVD (PECVD), or the like.

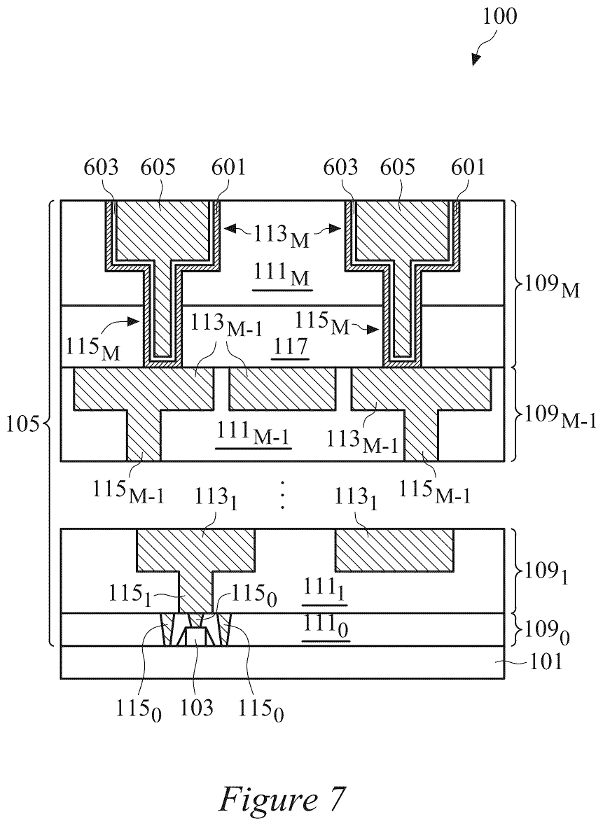

In some embodiments, the dielectric layers 111₀ comprises conductive plugs 115₀, and the dielectric layers 111₁ to 111_{M-1} comprise one or more conductive interconnects, such as conductive lines 113₁ to 113_{M-1} and conductive vias 115₁ to 115_{M-1}, respectively. The conductive plugs 115₀ electrically couple the one or more active and/or passive devices 103 to the conductive lines 113₁ to 113_{M-1} and the conductive vias 115₁ to 115_{M-1}. As described below in greater detail, conductive lines 113_{M} and conductive vias 115_{M} (not illustrated in FIG. 1, see FIG. 7) are formed in the dielectric layer 111_{M}.

In some embodiments, the conductive plugs 115₀, the conductive lines 113₁ to 113_{M-1} and the conductive vias 115₁ to 115_{M-1} may be formed using any suitable method, such as damascene, dual damascene, or the like. The conductive plugs 115₀, the conductive lines 113₁ to 113_{M-1} and the conductive vias 115₁ to 115_{M-1} may comprise conductive materials such as copper, aluminum, tungsten, combinations thereof, or the like. The conductive plugs 115₀, the conductive lines 113₁ to 113_{M-1} and the conductive vias 115₁ to 115_{M-1} may further comprise one or more barrier/adhesion layers (not shown) to protect the respective dielectric layers 111₀ to 111_{M-1} from diffusion and metallic poisoning. The one or more barrier/adhesion layers may comprise titanium, titanium nitride, tantalum, tantalum nitride, a combination thereof, or the like, and may be formed using physical vapor deposition (PVD), CVD, atomic layer deposition (ALD), a combination thereof, or the like. In an embodiment, the steps for forming the conductive plugs 115₀, the conductive lines 113₁ to 113_{M-1} and the conductive vias 115₁ to 115_{M-1} may include forming openings in the respective dielectric layers 111₀ to 111_{M-1}, depositing barrier/adhesion layers in the openings, depositing seed layers of a suitable conductive material over barrier/adhesion layers, and filling the openings with a suitable conductive material, for example, by plating, or other suitable methods. A chemical mechanical polishing (CMP) is then performed to remove excess materials overfilling the openings.

In some embodiments, etch stop layers (not shown) may be formed between adjacent ones of the dielectric layers 111₀ to 111_{M}. In the illustrated embodiment, such an etch stop layer (ESL) 117 is formed between the dielectric layers 111_{M-1} and 111_{M}. The etch stop layers aid in patterning the dielectric layers 111₀ to 111_{M} to form openings in the dielectric layers 111₀ to 111_{M}. A material for the etch stop layers is chosen such that etch rates of the etch stop layers are less then etch rates of corresponding ones of the dielectric layers 111₀ to 111_{M}, and such that the etch stop layers have a good adhesion with the corresponding ones of the dielectric layers 111₀ to 111_{M}. In the illustrated embodiment, an etch rate of the ESL 117 is less than an etch rate of the dielectric layer 111_{M}. As described below in greater detail, the ESL 117 is used for preventing oxidation/corrosion of the conductive lines 113_{M-1} and for preventing formation of hydride and hydroxyl impurities within the conductive lines 113_{M-1}.

In some embodiments, the ESL 117 may comprise metal-doped aluminum nitride (Al(M)N), where the metallic element M may include Cr, Al, Ti, Sn, Zn, Mg, Ag, or the like, and may be epitaxially deposited using CVD, PECVD, a combination thereof, or the like. In some embodiments, a thickness T₁ of the ESL 117 may be between about 100 nm and about 200 nm. In some embodiments, Al(M)N is in situ doped by using appropriate precursors for the metallic element M during the deposition. In alternative embodiments, Al(M)N may be formed by depositing AlN over the dielectric layer 111_{M} and the conductive lines 113_{M-1}, and subsequently doping AlN with the metallic element M using, for example, an implantation method. In some embodiments, an atomic percentage of the metallic element M in Al(M)N is between about 5% and about 10%. By choosing such a percentage of the metallic element M in Al(M)N, the etch selectivity and adhesion properties of Al(M)N are improved compared to AlN, without significantly affecting a conductivity of Al(M)N, such that Al(M)N provides sufficient insulating capabilities between adjacent conductive features, such as adjacent conductive lines 113_{M-1} and subsequently formed adjacent conductive vias 115_{M} (see FIG. 7).

In alterative embodiments, the ESL 117 may comprise one or more layers of dielectric materials such as oxides (such as silicon oxide, aluminum oxide, or the like), nitrides (such as SiN, or the like), oxynitrides (such as SiON, or the like), oxycarbides (such as SiOC, or the like), carbonitrides (such as SiCN, or the like), combinations thereof, or the like, and may be formed using spin-on coating, CVD, PECVD, ALD, a combination thereof, or the like.

Referring further to FIG. 1, a mask stack 119 is formed over the dielectric layer 111_{M}. As described below in greater detail, the mask stack 119 is used to aid in patterning of the dielectric layer 111_{M}. In some embodiments, the mask stack 119 comprises one or more mask layers. In the illustrated embodiment, the mask stack 119 comprises a first mask layer 119₁, and a second mask layer 119₂ over the first mask layer 119₁. In some embodiments, a thickness of the first mask layer 119₁ may be between about 150 nm and about 200 nm. In some embodiments, the first mask layer 119₁ includes a dielectric material, such as silicon oxide, silicon nitride, silicon oxynitride, silicon carbide, silicon carbonitride, a combination thereof, or the like, and may be formed using an oxidation process, ALD, CVD, PVD, a combination thereof, or the like. Accordingly, the first mask layer 119₁ may be also referred to as a dielectric mask layer 119₁. In some embodiments, the first mask layer 119₁ may act as an anti-reflective coating (ARC) and may be also referred to as an ARC 119₁.

In some embodiments, the first mask layer 119₁ comprises silicon carbide, which is doped with oxygen (O) and nitrogen (N). Contents of carbon and nitrogen in the first mask layer 119₁ may be tuned to achieve desired etching characteristics for the first mask layer 119₁. In some embodiments, the first mask layer 119₁ is substantially free from nitrogen. In such embodiments, the first mask layer 119₁ may be also referred to as a nitrogen-free ARC (NFARC) 119₁.

In some embodiments, the second mask layer 119₂ may comprise a metal nitride compound, such as titanium nitride (TiN), tantalum nitride (TaN), or the like, and may be formed using CVD, PECVD, ALD, a combination thereof, or the like. Accordingly, the second mask layer 119₂ may be also referred to as a metal mask layer 119₂. In some embodiments, a thickness of the second mask layer 119₂ may be between about 150 nm and about 200 nm. In alternative embodiments, the first mask layer 119₁ of the mask stack 119 may be omitted. In such embodiments, the mask stack 119 may comprise a layer of a nitride material.

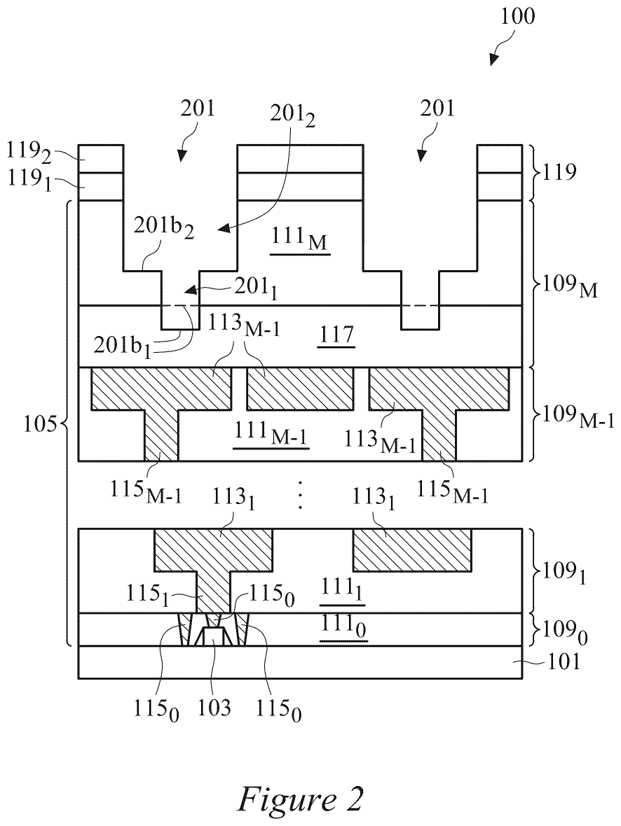

Referring to FIG. 2, the mask stack 119 and the dielectric layer 111_{M} are patterned to form openings 201 in the dielectric layer 111_{M}. The openings 201 comprise lower portions 201₁, which may be also referred to as via openings 201₁, and upper portions 201₂, which may be also referred to as line openings 201₂. In some embodiments, the openings 201 may be formed by a “via first” process. In other embodiments, the openings 201 may be formed by a “trench first” process.

In some embodiments when the openings 201 are formed using a “via first” process, the via openings 201₁ are formed before forming the line openings 201₂. In some embodiments, a first patterned mask (not shown) is formed on the second mask layer 119₂. A material of the first patterned mask is deposited on the second mask layer 119₂. The material of the first patterned mask is then irradiated (exposed), cured, and developed to remove a portion of the material of the first patterned mask, thereby forming the first patterned mask. In some embodiments, the first patterned mask may comprise a photoresist, or any suitable photo-patternable material.

In some embodiments, the first patterned mask is used to pattern the first mask layer 119₁, the second mask layer 119₂, and the dielectric layer 111_{M}, and form the via openings 201₁. Portions of the first mask layer 119₁, the second mask layer 119₂, and the dielectric layer 111_{M} unprotected by the first patterned mask are etched using a first etch process. In some embodiments, the first etch process may comprise one or more suitable etch processes, such as, for example, an anisotropic dry etch process, or the like. In an embodiment, the first etch process includes a reactive ion etch (RIE) process performed with processes gasses such as C₄F₈, CH₂F₂, CF₄, O₂, N₂, Ar, the like, or mixtures thereof. In an embodiment, a process gas mixture of a RIE process includes process gases that chemically etch the first mask layer 119₁, the second mask layer 119₂, and the dielectric layer 111_{M}. In some embodiments, the entire first patterned mask may be fully consumed prior to completion of the first etch process. In such embodiments, the first mask layer 119₁ and the second mask layer 119₂ are used as an etch mask to complete the first etch process.

In some embodiments, the first etch process stops when the via openings 201₁ reach the ESL 117, such that bottoms 201b₁ of the via openings 201₁ expose portions of the ESL 117. In alternative embodiments, the first etch process stops before the via openings 201₁ reach the ESL 117. In such embodiments, the bottoms 201b₁ of the via openings 201₁ expose portions of the dielectric layer 111_{M}. Subsequently, remaining portions of the first patterned mask, if any, are removed. In some embodiments when the first patterned mask is formed of a photoresist material, the remaining portions of the first patterned mask may be removed using, for example, an ashing process in combination with a wet clean process.

After forming the via openings 201₁, the line openings 201₂ are formed in the dielectric layer 111_{M}. In some embodiments, a second patterned mask (not shown) is formed on the second mask layer 119₂. A material of the second patterned mask is deposited on the second mask layer 119₂. The material of the second patterned mask is then irradiated (exposed), cured, and developed to remove a portion of the material of the second patterned mask, thereby forming the second patterned mask. In some embodiments, the second patterned mask may comprise a photoresist, or any suitable photo-patternable material.

In some embodiments, the second patterned mask is used to pattern the first mask layer 119₁, the second mask layer 119₂, and the dielectric layer 111_{M}, and to form the line openings 201₂. Portions of the first mask layer 119₁, the second mask layer 119₂, and the dielectric layer 111_{M} unprotected by the second patterned mask are etched using a second etch process. In some embodiments, the second etch process may comprise one or more suitable etch processes, such as, for example, an anisotropic dry etch process, or the like. In an embodiment, the second etch process includes a RIE process performed with processes gasses such as C₄F₈, CH₂F₂, CF₄, O₂, N₂, Ar, the like, or mixtures thereof. In an embodiment, a process gas mixture of a RIE process includes process gases that chemically etch the first mask layer 119₁, the second mask layer 119₂, and the dielectric layer 111_{M}. In some embodiments, the first etch process and the second etch process may be performed with different mixtures of process gases. In other embodiments, the first etch process and the second etch process may be performed with a same mixtures of process gases. In some embodiments, the entire second patterned mask may be fully consumed prior to completion of the second etch process. In such embodiments, the first mask layer 119₁ and the second mask layer 119₂ are used as an etch mask to complete the second etch process.

In some embodiments, the second etch process may further extend the via openings 201₁. In some embodiments when the ESL 117 is not exposed after the first etch process, the second etch process further etches the dielectric layer 111_{M}, such that the bottoms 201b₁ of the via openings 201₁ (shown by dashed lines in FIG. 2) expose portions of the ESL 117. In other embodiments when the ESL 117 is exposed after the first etch process, the second etch process etches the ESL 117, such that the via openings 201₁ partially extend into the ESL 117. In such embodiments, the bottoms 201b₁ of the via openings 201₁ are disposed within the ESL 117 below a topmost surface of the ESL 117. Subsequently, remaining portions of the second patterned mask, if any, are removed. In some embodiments when the second patterned mask is formed of a photoresist material, the remaining portions of the second patterned mask may be removed using, for example, an ashing process in combination with a wet clean process.

Referring further to FIG. 2, in alternative embodiments, the openings 201 are formed using a “trench first” process. In such embodiments, formation process of the openings 201 is similar to the “via first process” described above with a distinction that the line openings 201₂ are formed before forming the via openings 201₁.

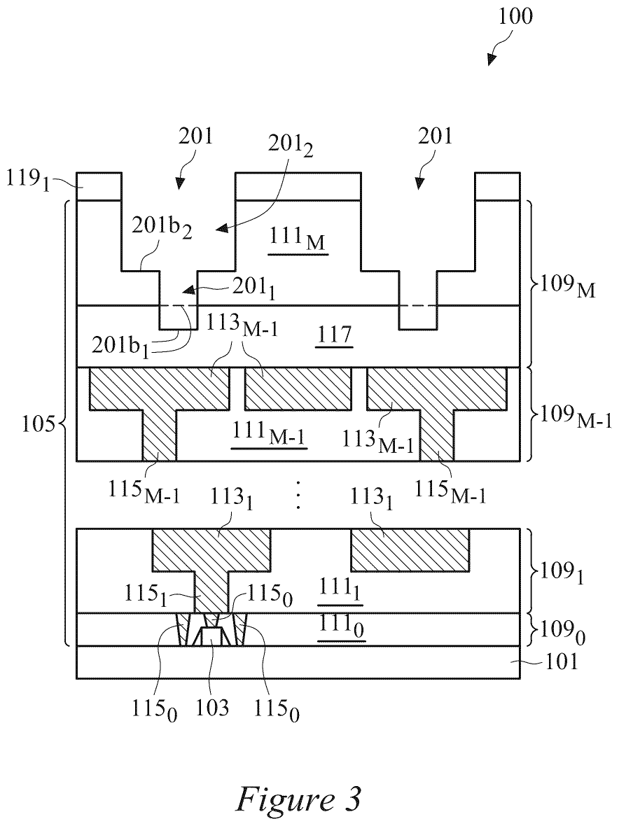

Referring to FIG. 3, the second mask layer 119₂ of the mask stack 119 is removed from the semiconductor structure 100. In some embodiments, the second mask layer 119₂ is removed using, for example, a blanket etch process. In some embodiments in which the second mask layer 119₂ is formed of TiN, a wet etch process with a solution comprising ammonium hydroxide (NH₄OH), hydrogen peroxide (H₂O₂) and deionized water (H₂O) may be used to remove the second mask layer 119₂. In other embodiments, other suitable removal processes may be used to remove the second mask layer 119₂. In some embodiments, the first mask layer 119₁ remains on the dielectric layer 111_{M} to protect the dielectric layer 111_{M} from a damage (e.g., plasma damage) induced by a subsequent etch process. Furthermore, as described below in greater detail, the first mask layer 119₁ acts as an etch mask for a subsequent etch process.

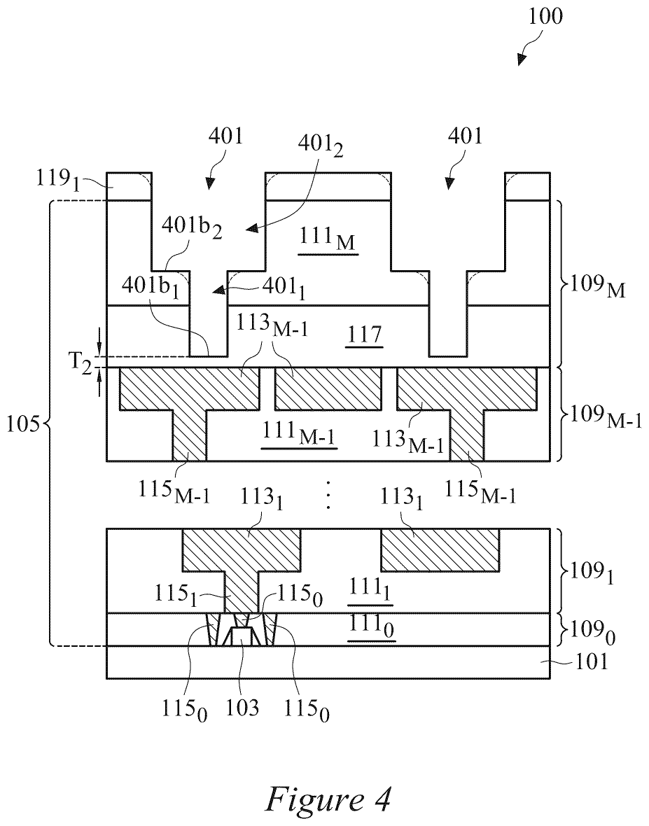

Referring to FIG. 4, a third etch process is performed on the semiconductor structure 100 to extend the openings 201 (see FIG. 3) towards the metallization layer 109_{M-1}, thereby forming openings 401. The openings 401 comprise lower portions 401₁, which may also be referred to as via openings 401₁, and upper portions 401₂, which may also be referred to as line openings 401₂. The via openings 401₁ correspond to the via openings 201₁ (see FIG. 3), and the line openings 401₂ correspond to the line openings 201₂ (see FIG. 3). In some embodiments, the third etch process removes portions of the dielectric layer 111_{M} disposed below the bottoms 201b₂ of the line openings 201₂ (see FIG. 3) and portions of the ESL 117 disposed below the bottoms 201b₁ of the via openings 201₁ (see FIG. 3). Accordingly, the bottoms 401b₁ of the via openings 401₁ are lower than the bottoms 201b₁ of the via openings 201₁, and the bottoms 401b₂ of the line openings 401₂ are lower than the bottoms 201b₂ of the line openings 201₂. Furthermore, the third etch process may also round corners of the openings 401 (illustrated by dashed lines in FIG. 4), such that the bottoms 401b₂ of the line openings 401₂ may smoothly join sidewalls of the via openings 401₁. In some embodiments, the third etch process may comprise one or more suitable etch processes, such as an anisotropic dry etch process, or the like. In an embodiment, the third etch process includes a RIE process performed with processes gasses such as C₄F₈, CH₂F₂, CF₄, O₂, N₂, Ar, the like, or mixtures thereof. In an embodiment, a process gas mixture of a RIE process includes process gases that chemically etch the second mask layer 119₂, the dielectric layer 111_{M}, and the ESL 117. In some embodiments, the third etch process and the first etch process may be performed with different mixtures of process gases. In other embodiments, the third etch process and the second etch process may be performed with different mixtures of process gases.

Referring further to FIG. 4, in the illustrated embodiment, a least a portion of the ESL 117 remains interposed between the bottoms 401b₁ of the via openings 401₁ and the conductive lines 113_{M-1}, such that the conductive lines 113_{M-1} are not exposed by the via openings 401₁. By not exposing the conductive lines 113_{M-1} during the third etch process, oxidation/corrosion of the conductive lines 113_{M-1} and formation of hydride and hydroxyl impurities within the conductive lines 113_{M-1} may be prevented. In some embodiments, portions of the ESL 117 interposed between the bottoms 401b₁ of the via openings 401₁ and the conductive lines 113_{M-1} may have a thickness T₂ between about 0.1 Å and about 0.5 Å. In some embodiments, such a range for the thickness T₂ allows for protecting the conductive lines 113_{M-1} from oxidation/corrosion and form formation of hydride and hydroxyl impurities.

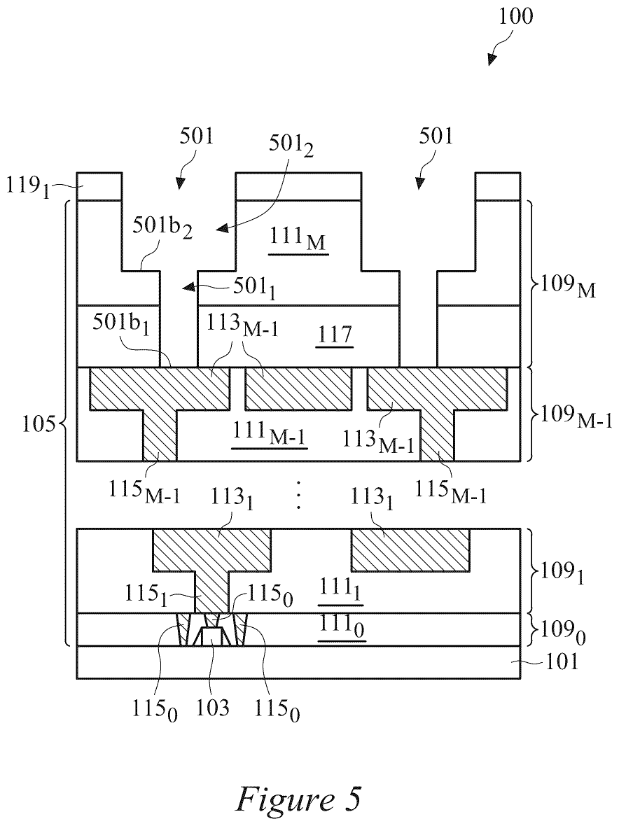

Referring to FIG. 5, the portions of the ESL 117 interposed between the bottoms 401b₁ of the via openings 401₁ (see FIG. 4) and the conductive lines 113_{M-1} are removed to expose underlying conductive lines 113_{M-1}, thereby forming openings 501. The openings 501 comprise lower portions 501₁, which may also be referred to as via openings 501₁, and upper portions 501₂, which may also be referred to as line openings 501₂. The via openings 501₁ correspond to the via openings 401₁ (see FIG. 4), and the line openings 501₂ correspond to the line openings 401₂ (see FIG. 4), with bottoms 501b₁ of the via openings 501₁ being lower than the bottoms 401b₁ of the via openings 401₁ (see FIG. 4). In some embodiments, the removal process for the ESL 117 may not substantially remove the dielectric layer 111_{M}. In such embodiments, bottoms 501b₂ of the line openings 501₂ may be approximately at a same level as the bottoms 401b₂ of the line openings 401₂ (see FIG. 4). In alternative embodiments, the removal process for the ESL 117 may also remove portions of the dielectric layer 111_{M}. In such embodiments, the bottoms 501b₂ of the line openings 501₂ may be lower than the bottoms 401b₂ of the line openings 401₂ (see FIG. 4).

Referring further to FIG. 5, in some embodiments, the portions of the ESL 117 interposed between the bottoms 401b₁ of the via openings 401₁ (see FIG. 4) and the conductive lines 113_{M-1} may be removed by sputtering, ion milling, or the like. The sputtering process may be performed by bombarding the desired portions of the ESL 117 with ions of an inert (non-reactive) gas, such as Argon (Ar), Nitrogen (N₂), a mixture thereof, or the like. In an embodiment, a process gas mixture of a sputtering process does not include process gases that chemically etch the ESL 117. By using inert gases to expose the conductive lines 113_{M-1}, oxidation/corrosion of the conductive lines 113_{M-1} may be prevented. In alternative embodiments, the portions of the ESL 117 interposed between the bottoms 401b₁ of the via openings 401₁ (see FIG. 4) and the conductive lines 113_{M-1} may be removed using other suitable removal processes, which does not oxidize the conductive lines 113_{M-1}.

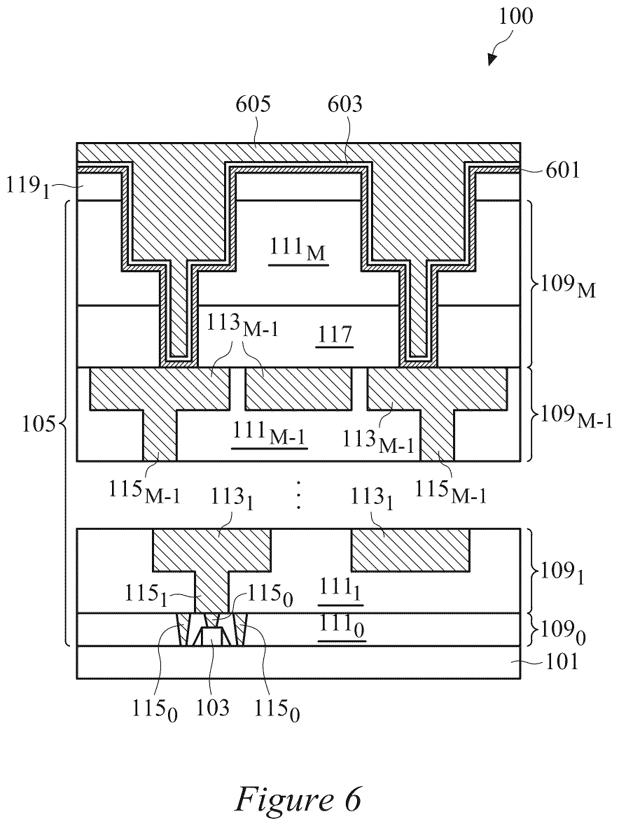

Referring to FIG. 6, the openings 501 (see FIG. 5) are filled with suitable conductive materials to form the conductive lines 113_{M} and the conductive vias 115_{M} (see FIG. 7). In some embodiments, one or more barrier/adhesion layers 601 are formed on bottoms and sidewalls of the openings 501. The one or more barrier/adhesion layers 601 protect the dielectric layer 111_{M} from diffusion and metallic poisoning. In some embodiments, the one or more barrier/adhesion layers 601 may comprise titanium, titanium nitride, tantalum, tantalum nitride, a combination thereof, or the like, and may be formed using PVD, CVD, ALD, a combination thereof, or the like.

In some embodiments, a seed layer 603 is formed over the one or more barrier/adhesion layers 601. The seed layer 603 may comprise copper, titanium, nickel, gold, manganese, a combination thereof, or the like, and may be formed by ALD, CVD, PVD, sputtering, a combination thereof, or the like. Subsequently, the openings 501 are filled with a conductive material 605. The conductive material 605 may comprise copper, aluminum, tungsten, combinations thereof, alloys thereof, or the like, and may be formed using, for example, by plating, or other suitable methods.

Referring to FIG. 7, portions of the one or more barrier/adhesion layers 601, the seed layer 603 and the conductive material 605 overfilling the openings 501 (see FIGS. 5 and 6) are removed to expose a top surface of the dielectric layer 111_{M}. In some embodiments, the portions of the one or more barrier/adhesion layers 601, the seed layer 603 and the conductive material 605 overfilling the openings 501 may be removed using a CMP process, a grinding process, an etching process, a combination thereof, or the like. Remaining portions of the one or more barrier/adhesion layers 601, the seed layer 603 and the conductive material 605 filling the via openings 501₁ (see FIGS. 5 and 6) form conductive vias 115_{M}, and remaining portions of the one or more barrier/adhesion layers 601, the seed layer 603 and the conductive material 605 filling the line openings 501₂ (see FIGS. 5 and 6) form conductive lines 113_{M}.

In some embodiments, the metallization layer 109_{M} may be the last metallization layer of the interconnect structure 105 and the formation of the metallization layer 109_{M} completes the formation of the interconnect structure 105. In other embodiments, the metallization layer 109_{M} may be an intermediate metallization layer of the interconnect structure 105. In such embodiments, additional metallization layers are formed over the metallization layer 109_{M} until the formation of the interconnect structure 105 is completed. In some embodiments, further processing steps may be performed on the semiconductor structure 100 after the formation of the interconnect structure 105 is completed. The further processing steps may include formation of contact pads and one or more passivation layers over the interconnect structure 105, formation of under-bump metallizations (UBMs) over the contact pads, and formation of connectors over the UBMs. Subsequently, the semiconductor structure 100 may be singulated into separate dies, which may further undergo various packaging processes.

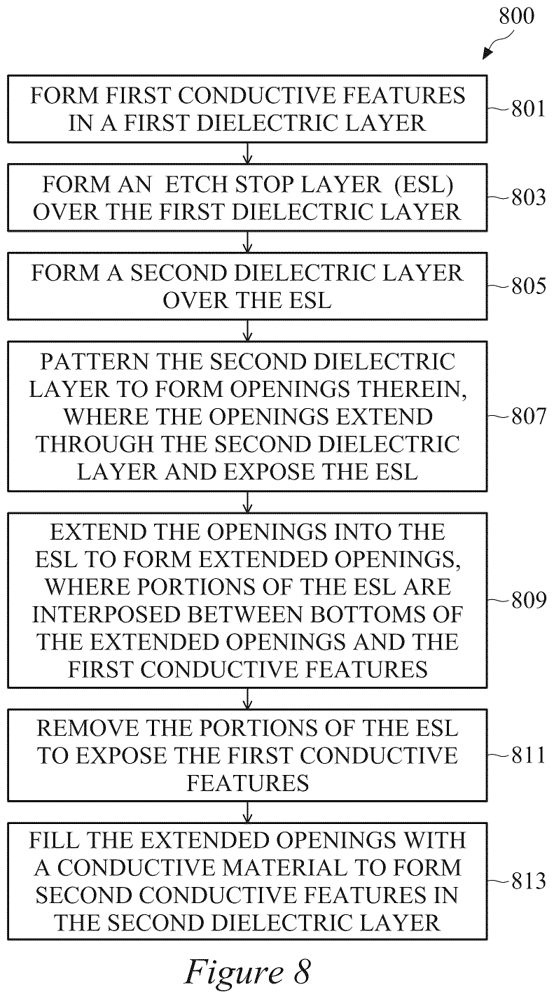

FIG. 8 is a flow diagram illustrating a method 800 of forming a semiconductor structure in accordance with some embodiments. The method 800 starts with step 801, when first conductive features (such as the conductive lines 113_{M-1} and the conductive vias 115_{M-1} illustrated in FIG. 1) are formed in a first dielectric layer (such as the dielectric layer 111_{M-1} illustrated in FIG. 1) as described above with reference to FIG. 1. In step 803, an etch stop layer (such as the ESL 117 illustrated in FIG. 1) is formed over the first dielectric layer as described above with reference to FIG. 1. In step 805, a second dielectric layer (such as the dielectric layer 111_{M} illustrated in FIG. 1) is formed over the etch stop layer as described above with reference to FIG. 1. In step 807, the second dielectric layer is patterned to form openings (such as the openings 201 illustrated in FIG. 2) in the second dielectric layer as described above with reference to FIG. 2. In step 809, the openings are extended into the etch stop layer to form extended openings (such as the openings 401 illustrated in FIG. 4), where portions of the etch stop layer are interposed between bottoms of the extended openings and the first conductive features as described above with reference to FIGS. 3 and 4. In step 811, the portions of the etch stop layer interposed between bottoms of the extended openings and the first conductive features are removed to expose the first conductive features as described above with reference to FIG. 5. In step 813, the extended openings are filled with a conductive material to form second conductive features (such as the conductive lines 113_{M} and the conductive vias 115_{M} illustrated in FIG. 7) in the second dielectric layer as described above with reference to FIGS. 6 and 7.

Various embodiments discussed herein allow for preventing oxidation/corrosion of interconnects and allow for preventing formation of hydride and hydroxyl impurities within interconnects by not fully removing the etch stop layer formed over the interconnects while chemically etching a dielectric layer formed over the etch stop layer to form openings for subsequently formed interconnects.

According to an embodiment, a method includes forming a first conductive feature in a first dielectric layer. An etch stop layer is formed over the first dielectric layer. A second dielectric layer is formed over the etch stop layer. The second dielectric layer and the etch stop layer are patterned to form an opening, where a portion of the etch stop layer is interposed between a bottom of the opening and the first conductive feature. The portion of the etch stop layer is sputtered to extend the opening toward the first conductive feature and form an extended opening, where the extended opening exposes the first conductive feature. The extended opening is filled with a conductive material to form a second conductive feature in the second dielectric layer.

According to another embodiment, a method includes forming a first conductive feature in a first dielectric layer. An etch stop layer is deposited over the first dielectric layer. A second dielectric layer is deposited over the etch stop layer. A first mask layer is deposited over the second dielectric layer. A second mask layer is deposited over the first mask layer. A first patterning process is performed on the second dielectric layer to form an opening in the second dielectric layer, where the first mask layer and the second mask layer are used as a combined mask. The second mask layer is removed. A second patterning process is performed on the second dielectric layer and the etch stop layer to extend the opening into the etch stop layer, where a bottom of the opening is disposed within the etch stop layer after performing the second patterning process. A sputtering process is performed on the bottom of the opening to expose a portion of the first conductive feature. A conductive material is deposited into the opening to form a second conductive feature in the second dielectric layer, where the second conductive feature is in electrical contact with the first conductive feature.

According to yet another embodiment, a method includes forming a metallization layer over a substrate. A metal-doped aluminum nitride layer is deposited over the metallization layer. A dielectric layer is deposited over the metal-doped aluminum nitride layer. A first mask layer is deposited over the dielectric layer. A second mask layer is deposited over the first mask layer. A first etch process is performed on the dielectric layer to form an opening in the dielectric layer, where the first mask layer and the second mask layer are used as a combined etch mask, and where the opening exposes the metal-doped aluminum nitride layer. A second etch process is performed on the dielectric layer and the metal-doped aluminum nitride layer to extend the opening into the metal-doped aluminum nitride layer, where the first mask layer is used as an etch mask, and where a portion of the metal-doped aluminum nitride layer is interposed between a bottom of the opening and a top surface of the metallization layer after performing the second etch process. A sputtering process is performed to remove the portion of the metal-doped aluminum nitride layer and expose a conductive feature of the metallization layer. The opening is filled with a conductive material.

According to yet another embodiment, a method includes forming a conductive line in a first dielectric layer. An etch stop layer is formed over the first dielectric layer. A second dielectric layer is formed over the etch stop layer. The second dielectric layer and the etch stop layer are etched to form an opening. A portion of the etch stop layer is interposed between a bottom of the opening and the conductive line. The portion of the etch stop layer is sputtered to extend the opening toward the conductive line and form an extended opening. The extended opening exposes a top surface of the conductive line.

According to yet another embodiment, a method includes forming a conductive line in a first dielectric layer. An etch stop layer is deposited over the first dielectric layer. A second dielectric layer is deposited over the etch stop layer. A first etch process is performed on the second dielectric layer to form an opening in the second dielectric layer. A second etch process is performed on the second dielectric layer and the etch stop layer to extend the opening into the etch stop layer. A bottom of the opening is disposed within the etch stop layer after performing the second etch process. A sputtering process is performed on the bottom of the opening to expose a portion of the conductive line.

According to yet another embodiment, a method includes forming a metallization layer over a substrate. An aluminum nitride layer is deposited over the metallization layer. A dielectric layer is deposited over the aluminum nitride layer. A first etch process is performed on the dielectric layer to form an opening in the dielectric layer. The opening exposes the aluminum nitride layer. A second etch process is performed on the dielectric layer and the aluminum nitride layer to extend the opening into the aluminum nitride layer. A portion of the aluminum nitride layer is interposed between a bottom of the opening and a top surface of the metallization layer after performing the second etch process. The portion of the aluminum nitride layer is removed to expose a conductive feature of the metallization layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first conductive feature in a first dielectric layer;
forming a metal-doped aluminum nitride layer over the first dielectric layer, the metal-doped aluminum nitride layer being an aluminum nitride doped with a metal element;
forming a second dielectric layer over the metal-doped aluminum nitride layer;
etching the second dielectric layer to form an opening, wherein a portion of the metal-doped aluminum nitride layer is interposed between a bottom of the opening and the first conductive feature;
sputtering the portion of the metal-doped aluminum nitride layer to extend the opening toward the first conductive feature and form an extended opening, wherein the extended opening exposes the first conductive feature; and
filling the extended opening with a conductive material to form a second conductive feature in the second dielectric layer.

2. The method of claim 1, wherein etching the second dielectric layer comprises etching a portion of the metal-doped aluminum nitride layer.

3. The method of claim 1, wherein the metal element is Cr, Al, Ti, Sn, Zn, Mg, or Ag.

4. The method of claim 1, wherein the metal-doped aluminum nitride layer has a thickness in a range 100 nm to 200 nm.

5. The method of claim 1, wherein an atomic percentage of the metal element in the metal-doped aluminum nitride layer is between 5% and 10%.

6. The method of claim 1, wherein forming the metal-doped aluminum nitride layer comprises:
forming an aluminum nitride layer; and
after forming the aluminum nitride layer, doping the aluminum nitride layer with the metal element.

7. The method of claim 1, wherein sputtering comprises sputtering with ions of argon or nitrogen.

8. A method comprising:
forming a metallization layer over a substrate;
forming a metal-doped aluminum nitride layer over the metallization layer, wherein the metal-doped aluminum nitride layer is an aluminum nitride layer doped with a metal dopant, wherein an atomic percentage of the metal dopant is in a range of 5% to 10%;
depositing a dielectric layer over the metal-doped aluminum nitride layer;
depositing one or more mask layers over the dielectric layer;
performing one or more etch processes on the dielectric layer to form an opening in the dielectric layer, wherein a bottom of the opening exposes the metal-doped aluminum nitride layer;
performing a sputtering process to remove a portion of the metal-doped aluminum nitride layer along the bottom of the opening and to expose a conductive feature of the metallization layer; and
filling the opening with a conductive material.

9. The method of claim 8, wherein performing one or more etch processes forms a recess in the metal-doped aluminum nitride layer.

10. The method of claim 8, wherein performing the sputtering process is performed using ions of an inert gas.

11. The method of claim 10, wherein the inert gas is argon or nitrogen.

12. The method of claim 8, wherein forming the metal-doped aluminum nitride layer comprises depositing an aluminum nitride layer.

13. The method of claim 12, wherein forming the metal-doped aluminum nitride layer comprises in situ doping the aluminum nitride layer with Cr, Al, Ti, Sn, Zn, Mg, or Ag.

14. The method of claim 8, wherein after performing the one or more etch processes, a thickness of 0.1 Å to 0.5 Å of the metal-doped aluminum nitride layer remains along the bottom of the opening.

15. A method comprising:
forming a first conductive feature in a first dielectric layer;
forming an aluminum nitride layer;
implanting the aluminum nitride layer with a metal dopant to form a metal-doped etch stop layer;
forming a second dielectric layer over the metal-doped etch stop layer;
forming an opening in the second dielectric layer, wherein a portion of the metal-doped etch stop layer is interposed between a bottom of the opening and the first conductive feature;
after forming the opening, sputtering the portion of the metal-doped etch stop layer to extend the opening and expose the first conductive feature; and
filling the opening with a conductive material to form a second conductive feature in the second dielectric layer.

16. The method of claim 15, wherein the metal dopant is Cr, Al, Ti, Sn, Zn, Mg, or Ag.

17. The method of claim 15, wherein implanting is performed in situ.

18. The method of claim 15, wherein the opening extends into the metal-doped etch stop layer.

19. The method of claim 15, wherein the sputtering uses ions of a gas that is non-reactive with aluminum nitride.

20. The method of claim 19, wherein the gas is nitrogen or argon.
